(19) United States
(12) Patent Application Publication
(10) Pub. No.: US 2010/0098883 A1
(43) Pub. Date: Apr. 22, 2010

(54) METHOD AND APPARATUS FOR PRODUCING ONE-DIMENSIONAL NANOSTRUCTURE

(75) Inventor: Daisuke Ito, Kanagawa (JP)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(73) Assignee: SONY CORPORATION, Tokyo (JP)

(21) Appl. No.: 12/551,899

(22) Filed: Sep. 1, 2009

(30) Foreign Application Priority Data
Sep. 2, 2008 (JP) 2008-224637

(51) Int. Cl. C23C 16/48; C23C 16/00

(52) U.S. Cl. 427/576; 427/569; 118/723 R; 977/891; 977/932

(57) ABSTRACT

A method and apparatus for producing one-dimensional nanostructures are disclosed. The production of the nanostructures is carried out by disposing a vanadium containing target facing a substrate; irradiating the target with laser light; and depositing target sublimation materials to the substrate under pressure conditions so that a plasma, which is generated by the laser light irradiation including target sublimation materials and gas atmosphere, does not substantially reach the substrate.

### BACKGROUND OF THE INVENTION

1. Field of the Invention

The invention relates to methods and apparatuses for producing one-dimensional nanostructures. More particularly, the invention relates to a method and apparatus for producing a nanowire including vanadium dioxide as a base material.

2. Description of the Related Art

While the compound vanadium dioxide is a monoclinic crystal at room temperature, it undergoes a metal-insulator phase transition at temperatures close to 68° C. and the transition to rutile type crystal takes place. At that time, it is reported its electrical resistance value changes by three orders of magnitude or more (see, P. Jin and S. Tanemura, Jpn. J. Appl. Phys. 33 1478 (1994)). Due to the large rate of resistance change with temperature, vanadium dioxide has been used as bolometer type infrared temperature sensors.

In addition, since another crystal phase of the vanadium dioxide is present different from the abovementioned phase, which is called VO₂ (B) without exhibiting metal-insulator phase transition, the vanadium dioxide with the structure exhibiting the monoclinic to rutile type phase transition is generally represented as VO₂ (M) (monoclinic form) or VO₂ (R) (rutile form). In the description which follows, the vanadium dioxide having structure exhibiting the phase transition is denoted by VO₂ (M).

Furthermore, a thin film including VO₂ (M) is reported to undergo a metal-insulator phase transition under electric field, the possibility as a field effect transistor or a switching element is considered (see, H-T. Kim et al., Applied Physics Letters 86, 242101 (2005)).

The crystallization of VO₂ (M) thin film by sputtering and so forth is reported previously (see, Japanese Unexamined Patent Application Publications No. 2007-224390 (in paragraphs 26 to 39) and No. 2007-515055 (in paragraphs 11 and 32)). However, since these VO₂ (M) thin films are formed having a polycrystalline structure, the number of crystal grains per unit area, the plane of crystal orientation, and the size of crystal grain are varied, a uniform phase transition is difficult to take place.

In order to obviate this difficulty, a method is disclosed for forming VO₂ (M) single crystal structures (see, B. Guiton et al., JACS, 127, 498 (2005)). However, the VO₂ (M) single crystal structures are very difficult to form and there are only few reports on the formation (see, M. Luo et al., Materials Chemistry and Physics, 104, 258 (2007)). On the other hand, VO₂ (B) can be formed with relative ease and almost all of the reports are related to this formation.

In regard to the method for forming a nanowire including VO₂ (M) single crystals, in particular, only two reported examples are found (see, B. Guiton et al., JACS, 127, 498 (2005) and J. Sohn et al., Nano Lett., 7, 1570 (2007)). These forming methods are related to the evaporation by heating (vapor-solid (VS) methods) using VO₂ (M) crystal powders.

### SUMMARY OF THE INVENTION

Although the VS method using VO₂ crystal powders mentioned above can form the nanowire including single crystal VO₂ (M), the growth temperatures for the nanowire are reported in the range of 600° C. or higher and 1100° C. or lower (that is, from 900° C. to 1000° C. according to B. Guiton et al., JACS, 127, 498 (2005), and from 600° C. to 700° C. according to J. Sohn et al., Nano Lett., 7, 1570 (2007)). Therefore, high growth temperatures become necessary and the growth time as long as two to five hours is also necessary. Furthermore, since the know-how for forming the VO₂ (M) crystal and for forming nanowires has a considerably large role to play, the method is not only insufficient in reproducibility, but also not suited to mass production, and this has been one of major obstacles to practical application.

Particularly, in the manufacturing process of semiconductor devices using semiconductor Si, and in order for the nanowire to be mounted in combination with Si devices and formed on a glass substrate, its low temperature and high-speed manufacturing process is necessary.

It is desirable to provide a method and apparatus capable of forming one-dimensional nanostructures such as VO₂ (M) nanowires and so forth at relatively low temperatures and high speeds with sufficient reproducibility.

According to an embodiment of the invention, there is provided a method for producing one-dimensional nanostructures, including the steps of disposing a vanadium containing target facing a substrate, irradiating the target having the present configuration with laser light, and depositing sublimation materials to the substrate under the pressure conditions so that a plasma (plume), which is generated by the irradiation including the target sublimation materials and a gas atmosphere, does not substantially reach the substrate, to thereby form one-dimensional nanostructures such as VO₂ (M) nanowires and so forth.

According to another embodiment of the invention, there is provided an apparatus for producing one-dimensional nanostructures such as VO₂ (M) nanowires and so forth, including substrate support means for supporting a substrate; target support means for supporting a vanadium containing target facing the substrate support means; laser light irradiation means for irradiating the vanadium containing target with laser light; and pressure control means for controlling the pressure of gas atmosphere so that a plasma (plume), which is generated including target sublimation materials and gas atmosphere, does not substantially reach the substrate.

According to the embodiments of the invention, since the target is sublimated by the irradiation of laser light under the pressure conditions so that the plasma does not substantially reach the substrate, the target sublimation materials are clusterized and subsequently adhered to the substrate, and single crystal one-dimensional nanostructures such as VO₂ (M) nanowires can be formed at low temperatures and high speeds with sufficient reproducibility, namely at temperatures as low as 450° C. or lower and in a short period of time as short as within several tens of minutes.

### BRIEF DESCRIPTION OF THE DRAWINGS

FIG. 1 is a schematic drawing generally illustrating a pulse laser deposition (PLD) apparatus according to an embodiment of the invention;

FIGS. 2A through 2E are schematic drawings respectively illustrating several features of the process using PLD method under various pressure conditions according to an embodiment of the invention;

FIGS. 3A and 3B respectively show SEM images of VO₂ thin film and VO₂ (M) nanowires, formed on c-plane sapphire substrate by the PLD method according to a specific example of an embodiment of the invention;

FIG. 4 shows an XRD pattern of the VO₂ (M) nanowires formed on the c-plane sapphire substrate by the PLD method according to a specific example of the embodiment;

FIG. 5 is a Raman spectrum of the VO₂ (M) nanowires formed according to a specific example of the embodiment;

FIGS. 6A through 6C are optical microscope images illustrating the temperature dependence of the growth of VO₂ (M) nanowires according to a specific example of the embodiment;

FIG. 7 is a schematic drawing generally illustrating an AFM electrical measurement evaluation system for evaluating electrical properties of the VO₂ (M) nanowires according to a specific example of the embodiment;

FIGS. 8A and 8B respectively show an AFM image and a current image of nanowires according to a specific example of the embodiment, in which both images are obtained during a simultaneous measurement of these images using AFM electrical measurement evaluation system;

FIG. 9A includes an I-V characteristic diagram of the VO₂ (M) nanowire according to a specific example of the embodiment, illustrating two cases for comparison, in which the AFM probe was applied onto the VO₂ (M) nanowire in a first case, while the probe was applied onto the substrate in a second case;

FIG. 9B shows a current versus time diagram of the VO₂ (M) nanowire according to a specific example of the embodiment, illustrating the dependence of ultraviolet ray irradiation (at wavelength of 255 nm) on the transient response characteristics;

FIGS. 10A and 10B are schematic drawings illustrating sensing elements including the VO₂ (M) nanowires according to a specific example of the embodiment;

FIGS. 11A and 11B are schematic drawings illustrating field effect transistors including the VO₂ (M) nanowires according to a specific example of the embodiment; and

FIG. 12 is a schematic drawing illustrating an exemplary aligning method for the VO₂ (M) nanowires according to a specific example of the embodiment.

### DESCRIPTION OF THE PREFERRED EMBODIMENTS

In the embodiments of the invention, it is desirable to use several gaseous components such as oxygen, nitrogen, argon, helium, and neon, individually or in combination as gas mixture, irradiate the abovementioned target with the laser light to sublimate and clusterize the target in the gas atmosphere under reduced pressures or normal pressure, and deposit the result to the substrate (in which this method is particularly called pulse laser deposition (PLD) detailed later on).

In this case, as the pressure conditions so that the plasma (plume) does not reach the substrate, it is desirable to have the pressure of gas atmosphere reduced to the range from 10 Pa (Pascal) to 100 Pa, and more preferably 50 Pa or higher in the range.

Although the one-dimensional nanostructures can be grown even under the temperature condition reduced to 350° C., it is desirable to be grown under elevated temperature conditions (substrate temperatures) such as at most 450° C. This can be carried out by providing a heating device to raise the temperature to 450° C. or lower.

In addition, the material composition of the abovementioned target may be selected among several vanadium containing materials such as elemental vanadium metal, vanadium dioxide, vanadium trioxide, vanadium tetroxide, vanadium pentoxide, and so forth.

The abovementioned single crystal one-dimensional nanostructures and particularly VO₂ (M) nanowires, which are formed using the target prepared as above by the method according to the embodiment of the invention, preferably include the monoclinic form of vanadium dioxide VO₂ (M) or the rutile form of vanadium dioxide VO₂ (R), as a base material.

The one-dimensional nanostructures of vanadium dioxide preferably include 3d transition metal elements such as Ti, Mn, Cr, Zn, and so forth, rare earth elements such as Er, Nb, Yb, and so forth, and Ta or W element, having a concentration of 50 percent by mass or less. This is devised based on the fact that the temperature of phase transition from the single crystal form can be changed by including these elements (for example, by including W element with a concentration of 2 percent by mass, the phase transition temperature decreases from 68° C. to 53° C.).

In addition, the one-dimensional nanostructures mentioned above may be adapted to the production of electronic devices utilizing at least one of the changes of the nanostructure property, including the resistance change by heat, resistance change by electric field, resistance change by light, resistance change by pressure or vibration, the change of infrared ray transmittance or reflectance by heat, change of infrared ray transmittance or reflectance by electric field, change of infrared ray transmittance or reflectance by light, change of infrared ray transmittance or reflectance by pressure or vibration, change of visible light transmittance or reflectance by heat, change of visible light transmittance or reflectance by electric field, change of visible light transmittance or reflectance by light, and change of visible light transmittance or reflectance by stress or vibration.

Still in addition, the one-dimensional nanostructures mentioned above may be adapted to the production of various electronic devices such as a temperature detection sensing element, light detection sensing element, field effect transistor element, nonvolatile memory element, photoelectric conversion element, light switching element, heat-ray modulation element, light modulation element, switching circuit element, phototransistor element, and optical memory element.

Hereinafter, a preferred embodiment of the invention will be explained in detail with reference to the drawings.

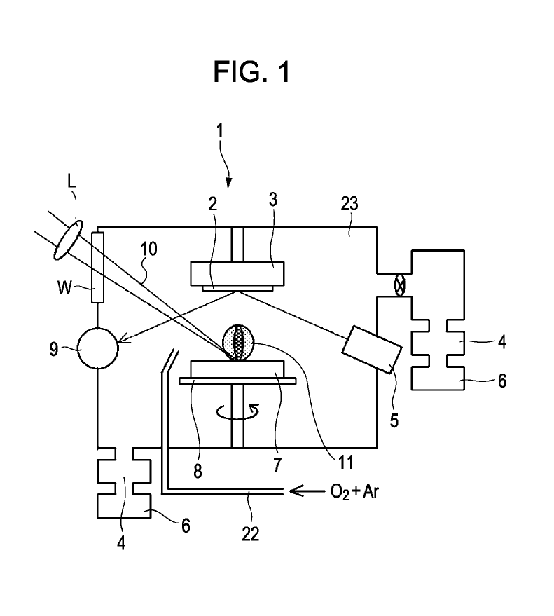

FIG. 1 illustrates a pulse laser deposition (PLD) apparatus 1 according to an embodiment of the invention.

Provided in a chamber 23 of the PLD apparatus 1 are a vanadium containing target (for example, VO₂ target) 7 disposed in a target support part 8, which is arranged facing a substrate 2 fixed to a susceptor (not shown) placed under a heater 3, and a gas inlet tubing 22 for introducing gaseous atmosphere (for example, mixed gas of O₂ and Ar).

The chamber 23 is additionally provided with a rotary pump 6 and turbine pump 4 for controlling the pressure of introduced gas, and, on the outer wall portion of the chamber 23, with an electron gun 5 and a reflected high-energy electron diffraction screen 9 for analyzing the surface state of the substrate 2 on receiving reflected beams of the electrons emitted from the electron gun 5.

In addition, a laser light source (not shown) is provided outside of the chamber 23, which is configured so that pulsed laser light 10 is focused with lens L to subsequently irradiate the VO₂ target 7 through the window portion W. As the laser light source, an ArF excimer laser may suitably be used, for example.

In the PLD apparatus according to the embodiment, a VO₂ nanowire 13 can be formed by disposing the VO₂ target 7 facing the substrate 2, irradiating the VO₂ target 7 having the present configuration with the pulsed laser light 10 to cause the sublimation (ablation), generating a plasma (plume) 11 including target sublimation materials and the mixed gas, controlling the pressure of gas atmosphere so that the plasma does not substantially reach the substrate 2, and depositing clusterized target sublimation materials to the substrate 2 under the pressure condition.

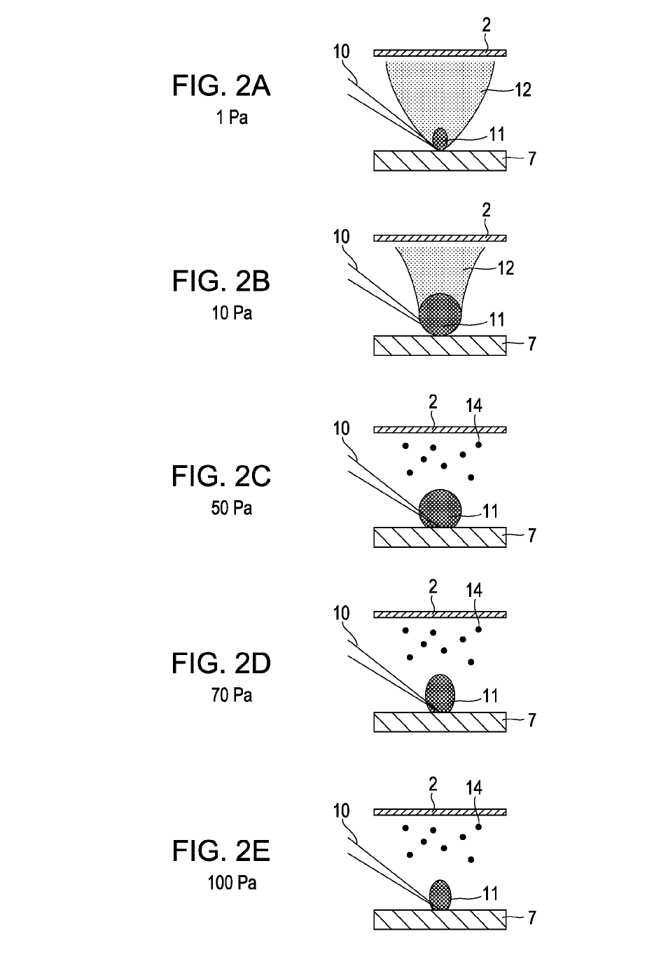

Referring to FIGS. 2A through 2E, several features of the plasma generation including the target sublimation materials and mixed gas are illustrated for comparison under various pressure conditions.

Referring first to FIG. 2A, when the pressure is set to 1 Pa, since a low-density plume 12 is diffused out from a high-density plume 11 to reach the surface of the substrate 2, a VO₂ thin film is only formed on the substrate 2. This feature is similar also in the case where the pressure is set to 10 Pa as shown in FIG. 2B.

In contrast, when the pressure is increased from 10 Pa to 50 Pa, as shown in FIG. 2C, the low-density plume 12 does not diffuse out from the spherical high-density plume 11 and a cluster 14 of target sublimation materials is generated to subsequently flow onto the substrate 2. Namely, since the plume does not reach the surface of the substrate 2 while the cluster 14 reaches and adheres to the surface, a single crystal VO₂ is grown on the substrate 2 from the cluster and the VO₂ nanowire can be formed.

In addition, as shown in FIG. 2D, when the pressure is increased further to 70 Pa, since the plume 11 becomes smaller and does not reach the surface of the substrate 2, the intended VO₂ nanowire is formed on the substrate. As shown in FIG. 2E, when the pressure is further increased to 100 Pa, the plume 11 becomes still smaller and the VO₂ nanowire can be formed suitably.

Therefore, by depositing the target sublimation materials as the cluster 14, which are generated by the irradiation of the laser light 10, to the substrate 2 under such condition of introduced gas pressure that the plume does not reach the substrate 2, the growth of intended VO₂ nanowire can be carried out.

The mechanism for attaining the above-mentioned formation of the nanowire is affected by the state of the plume (plasma including the target sublimation materials generated by the irradiation of the laser light 10 and the introduced gas), and the pressure of the introduced gas (atmospheric gas pressure) suitable for the plume not to reach the substrate 2 is set preferably ranging from 10 Pa to 100 Pa, more preferably 50 Pa or higher in this range.

With the gas pressure of 10 Pa or lower, as shown in FIGS. 2A and 2B, the plume 12 has the shape diverging toward the substrate 2, the VO₂ thin film alone is formed on the substrate 2; while for the gas pressure of 10 Pa or higher, further in the range of from 20 to 30 Pa or higher, and particularly of 50 Pa or higher, as shown in FIGS. 2C through 2E, the plume 11 becomes smaller having the shape of approximately sphere, the cluster 14 is generated to subsequently reach the substrate 2 and the VO₂ nanowire is thus grown.

This is considered as follows; because of the decrease in the mean free path of the target sublimation materials caused by the increase in the gas pressure to 10 Pa or higher, the target sublimation materials in a supersaturated state are clusterized to subsequently reach the substrate 2, and able to grow into the nanowire and/or nanowall when conditions are met.

Since the target 7 is sublimated instantaneously by the laser light 10, the mechanism for heating materials to high temperatures is not necessary as in the case of evaporation methods such as the VS method, for example. As a result, the nanowire can be formed at relatively low temperatures (especially at 450° C. or lower) and even at high speeds.

Comparing with the crystallization temperature of 400° C. for the VO₂ (M) thin film, which is disclosed in the aforementioned Japanese Unexamined Patent Application Publication No. 2007-224390, the substrate in the abovementioned VS method capable of forming VO₂ (M) nanowire is placed in high-temperature environment (ranging from 600 to 1100° C.) in order to carry out the evaporation of target materials by heating. However, in the abovementioned PLD method according to an embodiment of the present invention, a target heating evaporation mechanism is not necessary, as long as the pressure is appropriately controlled (possibly at 10 Pa or higher, and even at near normal pressures), and the growth of the VO₂ (M) nanowire becomes feasible at the temperatures as low as 450° C. or less and at high speeds, which has not been attained until now.

Although not related to the VO₂ nanowire, another example is reported (see, J. Jie et al., Appl. Phys. Lett. 86, 031909 (2005)) on the formation of ZnO nanowire using PLD apparatus at near normal pressures, in which since the temperature for the ZnO growth is in the range between 700° C. and 900° C., the growth is not feasible at the temperatures of 450° C. or lower. In addition, although a further example is also reported on the formation of MgO nanowire (see, J. Jie et al., Appl. Phys. Lett. 86, 031909 (2005) and A. Marcu et al., J. Appl. Phys. 102, 016102 (2007)), this growth is not feasible either at the temperatures of 450° C. or lower, since the temperature for the MgO growth is 800° C. or higher.

The embodiment of the present invention is explained below in detail with reference to specific examples.

### Formation of VO₂ Nanowire

A VO₂ (M) nanowire 24 was formed on a c-plane sapphire substrate by the PLD method as follows. By setting the ratio of O₂ to Ar for the introduced gas including O₂ and Ar to be the gas ratio of 1:1, and under additional conditions such as the gas pressure at 75 Pa (7.5×10⁻¹ Torr), the substrate temperature ranging from 400 to 420° C., the laser frequency at 5 Hz, and the distance between VO₂ target 7 and substrate 2 to be 50 mm, the VO₂ (M) nanowire was formed including VO₂ (M). The growth time of the VO₂ (M) nanowire during the process was 15 minutes which was considerably shorter than 2 to 5 hours reported in the aforementioned publication, Nano Lett., 7, 1570 (2007) by J. Sohn et al. In addition, the VO₂ crystal was found having a thin film structure when the O₂ gas was in excess, while the crystal was in a dot-shaped structure when the Ar gas was in excess, and the nanowire was able to be formed under the condition of the abovementioned mixing ratio.

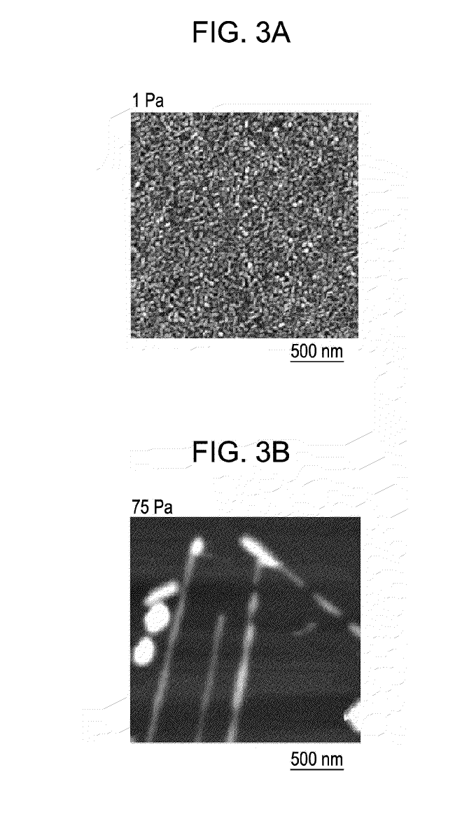

FIG. 3A shows a SEM image of the VO₂ (M) thin film formed by the PLD method at a low gas pressure of 1 Pa (1.0×10⁻² Torr) on the c-plane sapphire substrate, while FIG. 3B shows another SEM image of the VO₂ (M) nanowires formed at a high gas pressure of 75 Pa on the same substrate.

As shown in FIG. 3A, in the case of the low gas pressure it is found that the VO₂ (M) is formed only as a thin film including granular grains. On the other hand, at the high gas pressure as shown in FIG. 3B, it is found that the nanowires are grown in alignment with the crystal axis of the substrate. This indicates the crystal growth of the nanowires was carried out to be lattice-matched to the crystal axis of the c-plane sapphire (60° or 120°).

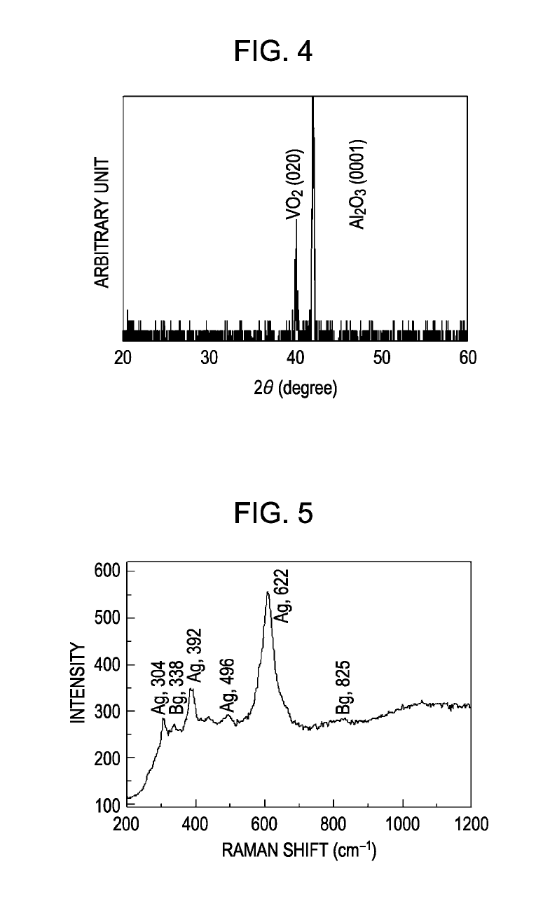

FIG. 4 shows an XRD pattern of the VO₂ (M) nanowire which was grown on the c-plane sapphire substrate. From the pattern, it is found the VO₂ (M) was grown to be orientated in the (020) plane.

FIG. 5 shows a Raman spectrum of the VO₂ (M) nanowires. According to the spectrum, it is confirmed that its Raman shifts are in agreement with the phonon vibration pattern of VO₂ (M). As a result of the mapping carried out using Ag (622 cm⁻¹) peak, which is the highest in intensity among the peaks, the same mapping image as the image from optical microscopy was obtained. It became clear from the results that the present structure is formed including only nanowires, but not the VO₂ thin film on the sapphire.

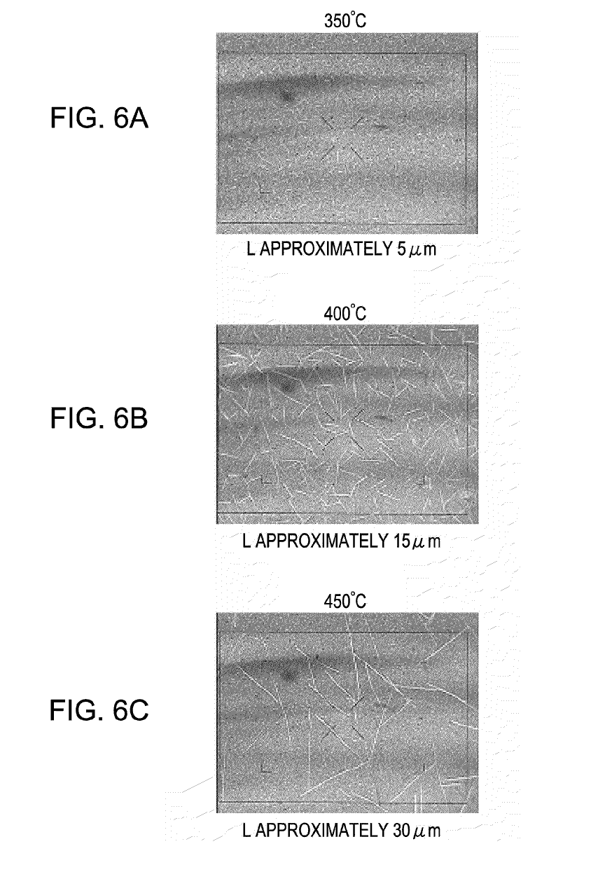

FIGS. 6A through 6C are high-power optical microscope images for illustrating the temperature dependence of the growth of VO₂ (M) nanowires.

First, as shown in FIG. 6A, nanowires can be formed even when the temperature is lowered to 350° C. However, as the temperature is lowered from 450° C. to 400° C., and further to 350° C., as respectively shown in FIGS. 6C, 6B, and 6A, the length of the nanowire become smaller (30 μm to 15 μm, and further to 5 μm), and it is found that the migration effect, which changes with the substrate temperature, affects the growth of nanowires. In addition, the above-mentioned temperatures (350° C. to 450° C.) do not arise undesirable effects on Si semiconductor manufacturing process such as, for example, wiring process, the temperatures are therefore compatible with the above processes and are suitable to be carried out in combination with the Si device processes.

As described hereinabove, the growth of the VO₂ nanowire using the PLD method has been confirmed for the first time by the present inventor, and the reduction of its growth temperature is also carried out ranging from 350° C. to 450° C., which is lower by even 200° C. to 300° C. than those in the past. These temperatures are compatible with Si semiconductor manufacturing process (Al wiring process steps and so forth), and the time for nanowire growth is also reduced to 15 minutes, which is as short as one-eighth of the time taken with previously known methods (VS method).

### Electrical Characteristics of VO₂ Nanowire

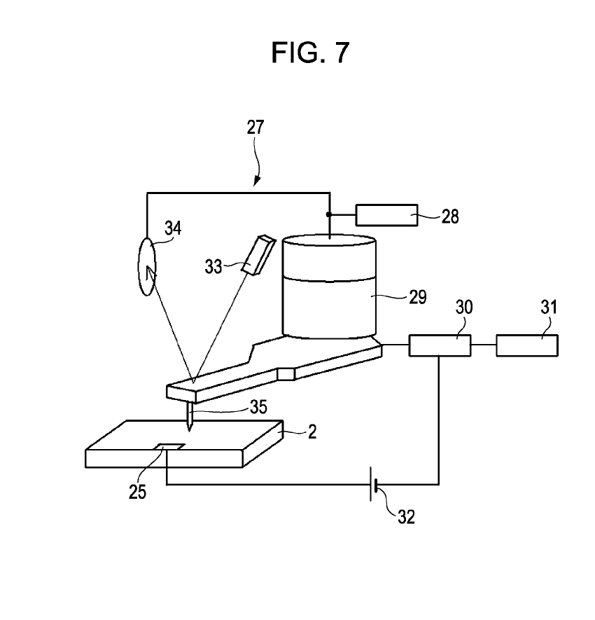

FIG. 7 shows an atomic force microscope (AFM) electrical measurement evaluation system 27 for evaluating electrical property of the VO₂ nanowires.

The evaluation system 27 includes an AFM image (display part) 28, scanner 29, amplifier 30, current image (display part) 31, power supply 32, laser light source 33, laser light detector 34, conductive AFM probe 35, and so forth. A substrate 2 is disposed facing the probe 35, in which the substrate has VO₂ nanowires formed thereon by the abovementioned method and is provided also thereon with an evaporated Au electrode 25.

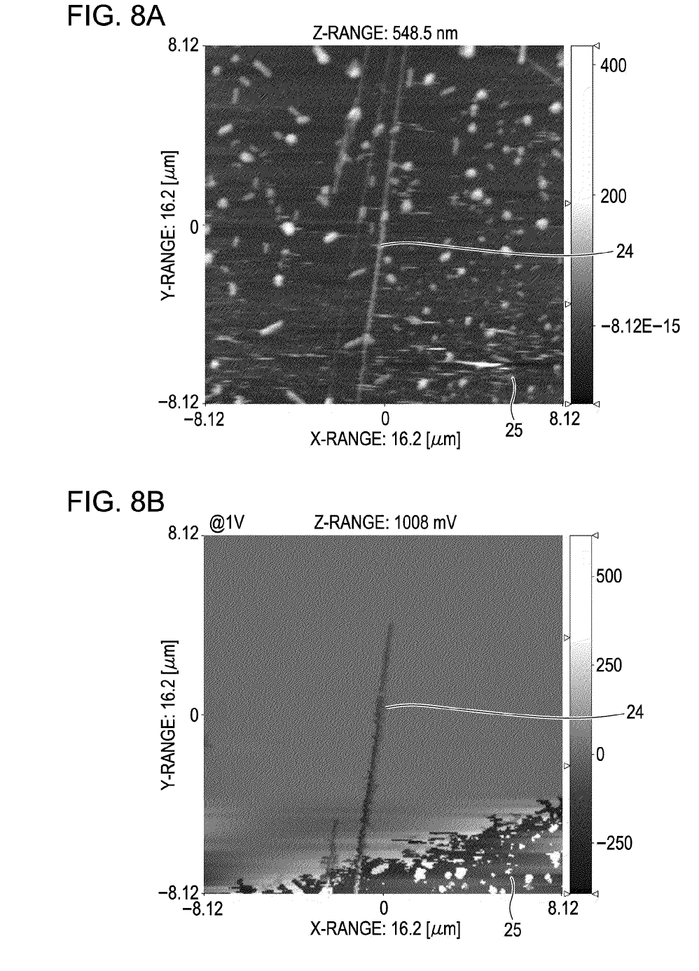

The electrical property evaluation was carried out using the system 27 on a single VO₂ nanowire formed on the substrate by the method mentioned above. FIG. 8A shows an AFM image of the VO₂ (M) nanowire 24 and FIG. 8B shows a current image of the nanowire corresponding to the AFM image, which are both obtained during a simultaneous measurement using the abovementioned AFM electrical measurement evaluation system 27.

According to FIG. 8A, the VO₂ (M) nanowire 24 is shown having one end thereof connected to the Au electrode 25 which is formed very thin by evaporation on the lower boundary side of the image, while an AFM probe serves as the other electrode.

In addition, from the results obtained by the simultaneous scanning of the AFM image and current image, respectively shown in FIGS. 8A and 8B, it was found that only the VO₂ (M) nanowire 24 connected to the Au electrode 25 was able to be observed to yield the current image.

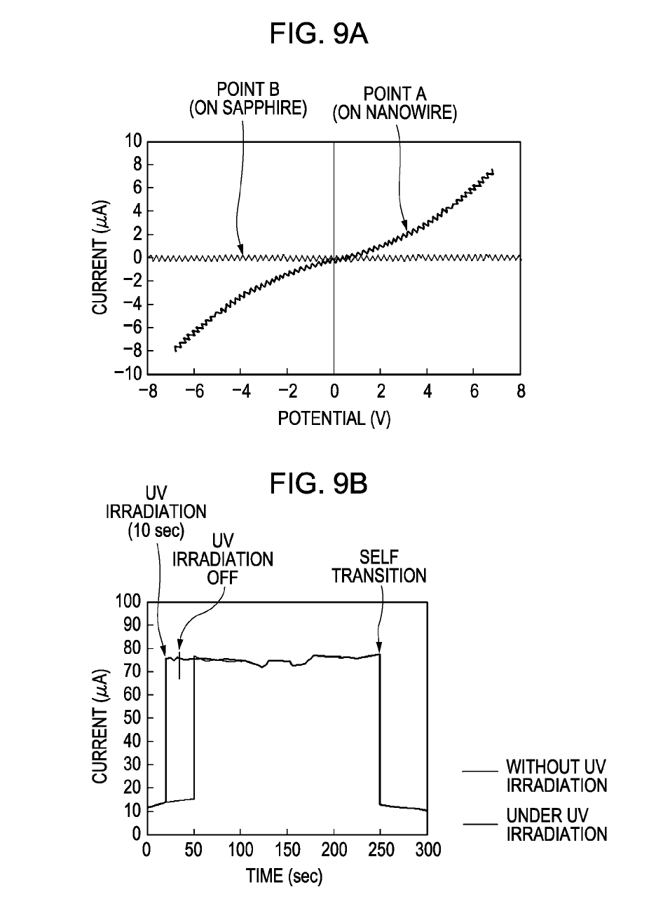

Next, the current voltage (I-V) characteristics of the VO₂ (M) nanowire 24 were measured. FIG. 9A illustrates the results obtained from the I-V measurement comparing two cases, in a first case where the AFM probe was applied to the point “A” on the VO₂ (M) nanowire 24, compared with a second case where the probe was applied to the point “B” (on the substrate) on the location other than the VO₂ (M) nanowire 24.

According to the results, it was found in a manner similar to the abovementioned current image results, that a symmetric I-V characteristic was obtained by applying positive and negative voltages on the VO₂ (M) nanowire 24, while an insulated state was found in the region other than the VO₂ (M) nanowire 24; and also confirmed from the results are a satisfactory accuracy of positional reproducibility with the above-mentioned AFM electric measurement evaluation system, and an excellent contact formed between the VO₂ (M) nanowire 24 and Au electrode 25. In addition, from the results of the I-V measurement, a metal-insulator transition of the VO₂ (M) nanowire 24 by the electric field was not found in this case.

Next, FIG. 9B shows the dependence of ultraviolet (UV) ray irradiation (at the wavelength of 255 nm) on the transient response characteristic (during 7 V application) of the VO₂ (M) nanowire 24.

According to the results, although a steep metal-insulator transition from a high resistance state to a low resistance state was observed about 50 seconds after the voltage application in the case of no ultraviolet ray irradiation, this is considered due to the heat generation induced by currents.

This transition phenomenon exhibits a steep feature compared with the thermal transition phenomenon reported in the aforementioned Japanese Unexamined Patent Application Publication No. 2007-224390. Unlike a polycrystalline structure such as of thin film, this difference can be considered due to one-step (primary) transition which is caused in the VO₂ (M) nanowire 24 as the single crystal structure.

In addition, it can also be found with the VO₂ (M) nanowire 24 that the one-step transition is caused by ultraviolet ray irradiation with no dependence on the time of voltage application. That is, when the ultraviolet ray irradiation is carried out for 10 seconds without voltage application, a steep metal-insulator transition takes place at that time and this is of considerable interest in light of the fact that the transition occurs in the time shorter than the case without the UV ray irradiation. Furthermore, after the ultraviolet ray irradiation and remaining in the metal state for 200 seconds or more, a one-step transition into the insulator is also observed; this phenomenon is also assumed due to the single crystal structure without grain boundaries.

Still in addition, such a photo-induced phase transition is reported for the VO₂ (M) thin film (see, S. Lysenko et al., PHYSICAL REVIEW B 76, 035104 (2007)), this is considered to be a phenomenon strongly correlated with orbitals and phonons.

If the principle of these phenomena is made clear and found to be controllable by various stimuli, it will become possible to design novel switching devices utilizing the strongly correlated metal to insulator transition so as to undergo the transition not only as the optical and/or electronic switch but also as the switch capable of being activated by all kinds of stimuli such as vibration, heat, magnetic field, and so forth.

With the VO₂ (M) nanowire 24 grown through the abovementioned process, the control of growth direction such as the parallel alignment, 60° alignment, and so forth has become possible by utilizing the lattice-matching capability attained by the selection of single crystal substrate 2.

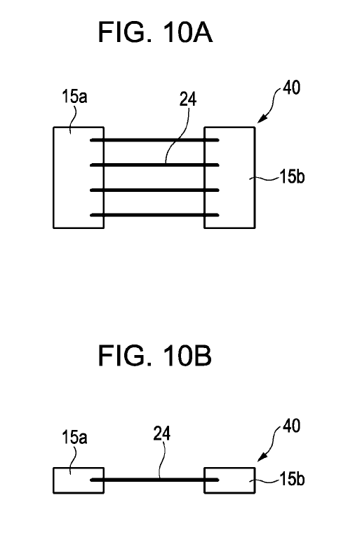

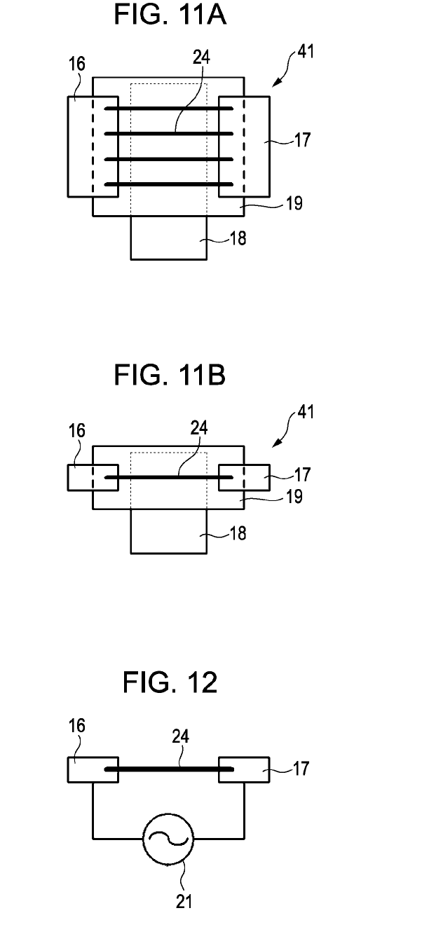

Therefore, using the nanowire as the wiring between electrodes, several device elements can be provided such as a high-sensitive temperature detection sensing element or a light detection sensing element shown in FIGS. 10A and 10B, or a field effect transistor (FET) or a memory device element shown in FIGS. 11A and 11B.

FIG. 10A illustrates a sensing element 40 which is formed including two or more VO₂ (M) nanowires 24 attached in parallel between opposing electrodes, 15a and 15b, and FIG. 10B illustrates the case where one VO₂ (M) nanowire 24 is included. The detection of temperature or light is carried out by sensing the change of the current flowing between both electrodes induced by temperature or light. In addition, utilizing such property of the VO₂ (M) nanowire 24 that light does not penetrate when a voltage is applied between both the electrodes and that the light penetrates when the applied voltage is turned off, it can be adapted to an optical IC for optical communications. FIG. 11A illustrates a back gate type FET 41, which is formed on a gate insulating film 19 disposed on a gate electrode 18, including a source electrode 16 and a drain electrode 17 disposed facing each other, and two or more VO₂ (M) nanowires 24 attached in parallel between these electrodes to form a channel region. In addition, FIG. 11B illustrates the case where the channel region is formed including one VO₂ (M) nanowire 24.

The scaling of these respective elements, which are shown in FIGS. 10A and 10B, and FIGS. 11A and 11B, can be controlled by the number of the VO₂ (M) nanowires 24. In this case, the VO₂ (M) nanowires 24 can be removed from the substrate 2 by applying ultrasonic waves in organic liquid such as alcohol or acetone, or in water, and the formation of electronic device using either single nanowire or a predetermined number of nanowires thus becomes feasible.

FIG. 12 illustrates the example in which a single nanowire is arranged using an electrophoresis method. According to this aligning method, for example, by rinsing out unnecessary nanowires held on the substrate with ethanol and thereafter applying a high frequency electric field of the order of about 1 to 10 V and 1 kHz to 1 MHz between the source electrode 16 and drain electrode 17 in ethanol by a high frequency power supply 21, nanowires in the region other than between both the electrodes are removed. Accordingly, intended nanowires can be selectively attached to, and spanned between the electrodes.

While the present invention has been described hereinabove with reference to the embodiments and specific examples, numerous modifications of the examples are possible based on the technical thought of the invention.

For example, the pressure, mixing ratio, and the kind of the abovementioned atmospheric gas, the kind of the target and laser light, and so forth can be changed according to the size, quality of the material, and so forth of the nanowire to form. In addition, the quality of the substrate material which forms the nanowire can also be selected in various ways, where appropriate.

The present application contains subject matter related to that disclosed in Japanese Priority Patent Application JP 2008-224637 filed in the Japan Patent Office on Sep. 2, 2008, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A method for producing a one-dimensional nanostructure, the method comprising the steps of:
disposing a vanadium containing target facing a substrate;
irradiating the target having a present configuration with laser light; and
depositing target sublimation materials to the substrate under pressure conditions so that a plasma does not substantially reach the substrate, the plasma being generated by the irradiation including the target sublimation materials and a gas atmosphere.

2. The method according to claim 1, wherein
the step of irradiating with laser light is carried out in a gas atmosphere at one of a reduced pressure and a normal pressure, the gas atmosphere including at least one of oxygen, nitrogen, argon, helium, and neon, individually or in combination as a gas mixture.

3. The method according to claim 2, wherein
a pressure of the gas atmosphere is decreased ranging from 10 Pa to 100 Pa.

4. The method according to claim 3, wherein
the pressure of the gas atmosphere is adjusted to be 50 Pa and higher.

5. The method according to claim 3, wherein
the one-dimensional nanostructure is formed under elevated temperature conditions of at most 450° C.

6. The method according to claim 1, wherein
a material constituting the target is a vanadium containing material including at least one of elemental vanadium metal, vanadium dioxide, vanadium trioxide, vanadium tetroxide, and vanadium pentoxide.

7. The method according to claim 1, wherein
a base material of the one-dimensional nanostructure is one of a monoclinic form of vanadium dioxide and a rutile form of vanadium dioxide.

8. The method according to claim 7, wherein
a nanowire is formed as the one-dimensional nanostructure.

9. The method according to claim 7, wherein
the vanadium dioxide include one of 3d transition metal elements including at least Ti, Mn, Cr, and Zn; rare earth elements including at least Er, Nb, and Yb; and Ta and W; having a concentration of 50 percent by mass at most.

10. The method according to claim 1, wherein
the one-dimensional nanostructure is adapted to a production of an electronic device utilizing at least one of
a resistance change by heat,
a resistance change by electric field,
a resistance change by light,
a resistance change by one of pressure and vibration,
a change of one of infrared ray transmittance and reflectance by heat,
a change of one of infrared ray transmittance and reflectance by electric field,
a change of one of infrared ray transmittance and reflectance by light,
a change of one of infrared ray transmittance and reflectance by one of pressure and vibration,
a change of one of visible light transmittance and reflectance by heat,
a change of one of visible light transmittance and reflectance by electric field,
a change of one of visible light transmittance and reflectance by light, and
a change of one of visible light transmittance and reflectance by one of stress and vibration.

11. The method according to claim 1, wherein
the one-dimensional nanostructure is adapted to a production of one of
a temperature detection sensing element,
a light detection sensing element,
a field effect transistor element,
a nonvolatile memory element,
a photoelectric conversion element,
a light switching element,
a heat-ray modulation element,
a light modulation element,
a switching circuit element,
a phototransistor element, and
an optical memory element.

12. An apparatus for producing a one-dimensional nanostructure, the apparatus comprising:
substrate support means for supporting a substrate;
target support means for supporting a vanadium containing target disposed facing the substrate support means;
laser light irradiation means for irradiating the vanadium containing target with laser light; and
pressure control means for controlling a pressure of gas atmosphere so that a plasma does not substantially reach the substrate, the plasma being generated including target sublimation materials and a gas atmosphere.

13. The apparatus according to claim 12, wherein
the target is irradiated with the laser light in a gas atmosphere at one of a reduced pressure and a normal pressure, the gas atmosphere including at least one of oxygen, nitrogen, argon, helium, and neon, individually or in combination as a gas mixture.

14. The apparatus according to claim 13, wherein
a pressure of the gas atmosphere is decreased ranging from 10 Pa to 100 Pa.

15. The apparatus according to claim 14, wherein
the pressure of the gas atmosphere is adjusted to be 50 Pa and higher.

16. The apparatus according to claim 14, further comprising:
a heating unit for producing the one-dimensional nanostructure under elevated temperature conditions of at most 450° C.

17. The apparatus according to claim 12, wherein
a material constituting the target is a vanadium containing material including at least one of elemental vanadium metal, vanadium dioxide, vanadium trioxide, vanadium tetroxide, and vanadium pentoxide.

18. The apparatus according to claim 12, wherein
a base material of the one-dimensional nanostructure is one of a monoclinic form of vanadium dioxide and a rutile form of vanadium dioxide.

19. The apparatus according to claim 18, wherein
a nanowire is formed as the one-dimensional nanostructure.

20. The apparatus according to claim 18, wherein
the vanadium dioxide include one of 3d transition metal elements including at least Ti, Mn, Cr, and Zn; rare earth elements including at least Er, Nb, and Yb; and Ta and W; having a concentration of 50 percent by mass at most.

21. An apparatus for forming a one-dimensional nanostructure, the apparatus comprising:
a substrate support unit supporting a substrate;
a target support unit supporting a vanadium containing target disposed facing the substrate;
a laser light irradiation unit irradiating the vanadium containing target with laser light; and
a pressure control unit controlling a pressure of gas atmosphere so that a plasma does not substantially reach the substrate, the plasma being generated including target sublimation materials and a gas atmosphere.
